(19) United States
(12) Patent Application Publication
(10) Pub. No.: US 2024/0098385 A1
(43) Pub. Date: Mar. 21, 2024

(54) IMAGE SENSOR AND ELECTRONIC DEVICE

(71) Applicant: SONY SEMICONDUCTOR SOLUTIONS CORPORATION, KANAGAWA (JP)

(72) Inventor: REN HIYOSHI, KANAGAWA (JP)

(21) Appl. No.: 18/264,159

(22) PCT Filed: Jan. 6, 2022
(86) PCT No.: PCT/JP2022/000161

§ 371 Date: Aug. 3, 2023

(30) Foreign Application Priority Data
Feb. 17, 2021 (JP) 2021-023132

(51) Int. Cl. H04N 25/77; H01L 27/146; H04N 25/47

(52) U.S. Cl. CPC H04N 25/77; H01L 27/14605; H01L 27/14621; H01L 27/14641; H04N 25/47; H01L 27/14634; H04N 25/79

(57) ABSTRACT

The present disclosure relates to an image sensor and an electronic device capable of further improving performance. An image sensor includes: a photoelectric conversion unit provided for each of a plurality of pixels arranged in a matrix on a sensor surface; a TG transistor that transfers a charge generated by photoelectric conversion in the photoelectric conversion unit to an FD node; and a TGD transistor that transfers a charge generated by photoelectric conversion in the photoelectric conversion unit to an SN node. In addition, at least a part of a predetermined number of the pixels included in an intensity sharing unit that shares and uses the FD node and a predetermined number of the pixels included in an event sharing unit that shares and uses the SN node have different sharing destinations. The present technology can be applied to, for example, an image sensor that detects occurrence of an event and acquires an image.

### TECHNICAL FIELD

The present disclosure relates to an image sensor and an electronic device, and more particularly to an image sensor and an electronic device capable of further improving performance.

### BACKGROUND ART

Conventionally, there has been developed an image sensor that detects, as an event, that an amount of light received by a photodiode exceeds a threshold value for each pixel in real time, and reads a pixel signal corresponding to an intensity from the pixel to acquire an image.

For example, Patent Document 1 discloses a solid-state imaging device in which pixel transistors are arranged so as to improve the light receiving efficiency of sensors capable of detecting an event and detecting intensity.

### CITATION LIST

### Patent Document

Patent Document 1: Japanese Patent Application Laid-Open No. 2020-68484

### SUMMARY OF THE INVENTION

### Problems to be Solved by the Invention

Meanwhile, in the solid-state imaging device disclosed in Patent Document 1, a pixel transistor for event detection and a pixel transistor for intensity detection are required for each pixel, and the number of pixel transistors provided for each pixel is increased. Thus, it has been conventionally difficult to achieve miniaturization, expansion of a light receiving section, and the like. Furthermore, the conventional solid-state imaging device has a configuration in which a pixel transistor for event detection and a pixel transistor for intensity detection are arranged adjacent to each other. Thus, there is a concern that a detection error may occur due to coupling of both control lines when these pixel transistors are simultaneously driven. Therefore, it is demanded to improve performance by miniaturizing pixels, enlarging a light receiving section, suppressing a detection error, and the like.

The present disclosure has been made in view of such a situation, and an object thereof is to further improve performance.

### Solutions to Problems

An image sensor according to an aspect of the present disclosure includes: a photoelectric conversion unit provided for each of a plurality of pixels arranged in a matrix on a sensor surface; a first transfer transistor that transfers a charge generated by photoelectric conversion in the photoelectric conversion unit to a first node; and a second transfer transistor that transfers a charge generated by photoelectric conversion in the photoelectric conversion unit to a second node different from the first node, in which at least a part of a predetermined number of the pixels included in a first sharing unit that shares and uses the first node and a predetermined number of the pixels included in a second sharing unit that shares and uses the second node have different sharing destinations.

An electronic device according to an aspect of the present disclosure includes: a photoelectric conversion unit provided for each of a plurality of pixels arranged in a matrix on a sensor surface; a first transfer transistor that transfers a charge generated by photoelectric conversion in the photoelectric conversion unit to a first node; and a second transfer transistor that transfers a charge generated by photoelectric conversion in the photoelectric conversion unit to a second node different from the first node, and includes an image sensor in which at least a part of a predetermined number of the pixels included in a first sharing unit that shares and uses the first node and a predetermined number of the pixels included in a second sharing unit that shares and uses the second node have different sharing destinations.

In one aspect of the present disclosure, a photoelectric conversion unit is provided for each of a plurality of pixels arranged in a matrix on a sensor surface, a charge generated by photoelectric conversion in the photoelectric conversion unit is transferred to a first node by a first transfer transistor, and a charge generated by photoelectric conversion in the photoelectric conversion unit is transferred to a second node different from the first node by a second transfer transistor. In addition, at least a part of a predetermined number of the pixels included in a first sharing unit that shares and uses the first node and a predetermined number of the pixels included in a second sharing unit that shares and uses the second node have different sharing destinations.

### BRIEF DESCRIPTION OF DRAWINGS

FIG. 1 is a circuit diagram illustrating a configuration example of an embodiment of an image sensor to which the present technology is applied.

FIG. 2 is a wiring diagram illustrating an example of a wiring configuration of an image sensor.

FIG. 3 is a diagram illustrating an example of a waveform of a vertical scanning signal for driving an image sensor.

FIG. 4 is a diagram for describing driving in an intensity detection period.

FIG. 5 is a diagram for describing driving in an event detection period.

FIG. 6 is a diagram for describing a first driving method of having an intensity detection period and an event detection period in parallel.

FIG. 7 is a diagram for describing a second driving method of having an intensity detection period and an event detection period in parallel.

FIG. 8 is a diagram illustrating a first arrangement example of transistors.

FIG. 9 is a diagram illustrating a second arrangement example of transistors.

FIG. 10 is a diagram illustrating a third arrangement example of transistors.

FIG. 11 is a diagram illustrating a fourth arrangement example of transistors.

FIG. 12 is a diagram illustrating a fifth arrangement example of transistors.

FIG. 13 is a view illustrating an example of a planar layout of a sensor substrate and a transistor substrate.

FIG. 14 is a diagram illustrating a first arrangement example of color filters.

FIG. 15 is a diagram illustrating a second arrangement example of color filters.

FIG. 16 is a diagram illustrating a third arrangement example of color filters.

FIG. 17 is a diagram illustrating a fourth arrangement example of color filters.

FIG. 18 is a diagram illustrating a fifth arrangement example of color filters.

FIG. 19 is a diagram illustrating a sixth arrangement example of color filters.

FIG. 20 is a block diagram illustrating a configuration example of an imaging device.

FIG. 21 is a view illustrating a usage example of an image sensor.

### MODE FOR CARRYING OUT THE INVENTION

Hereinafter, a specific embodiment to which the present technology is applied will be described in detail with reference to the drawings.

<Configuration Example of Image Sensor>

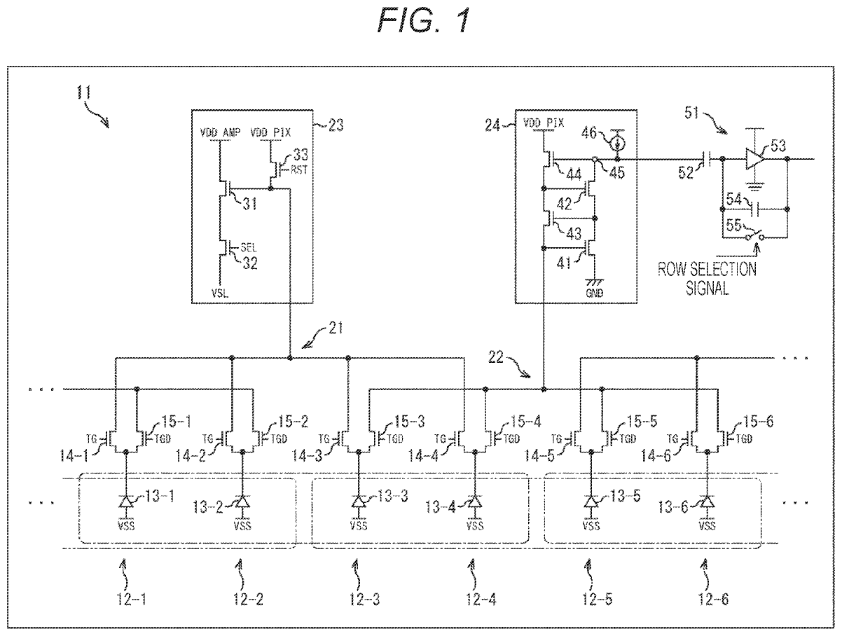

FIG. 1 is a circuit diagram illustrating a configuration example of an embodiment of an image sensor to which the present technology is applied.

An image sensor 11 includes a plurality of pixels 12 arranged in a matrix on a sensor surface that receives light, and detect occurrence of an event for each pixel 12, so as to acquire an image.

Each pixel 12 includes a photodiode (PD) 13, a transfer transistor (hereinafter, referred to as a TG transistor) 14 for intensity detection, and a transfer transistor (hereinafter, referred to as a TGD transistor) 15 for event detection.

FIG. 1 illustrates a circuit diagram of six pixels 12-1 to 12-6 out of the plurality of pixels 12 included in the image sensor 11. As illustrated, the image sensor 11 includes an intensity reading circuit 23 shared by the four pixels 12-1 to 12-4 via an intensity detection node (hereinafter, referred to as an FD node) 21, and a logarithmic conversion circuit 24 shared by the four pixels 12-3 to 12-6 via an event detection node (hereinafter, referred to as an SN node) 22.

In the pixels 12-1 to 12-4, one ends of the TG transistors 14-1 to 14-4 are connected to the PDs 13-1 to 13-4, respectively, and the other ends of the TG transistors 14-1 to 14-4 are connected to the FD node 21. Similarly, in the pixels 12-3 to 12-6, one ends of the TGD transistors 15-3 to 15-6 are connected to the PDs 13-3 to 13-6, respectively, and the other ends of the TGD transistors 15-3 to 15-6 are connected to the SN node 22.

The TG transistors 14-1 to 14-4 transfer the charges generated by photoelectric conversion in the PDs 13-1 to 13-4 to the FD node 21 according to respective transfer signals TG. The FD node 21 temporarily accumulates these charges.

The TGD transistors 15-3 to 15-6 transfer the charges generated by photoelectric conversion in the PDs 13-3 to 13-6 to the SN node 22 according to the respective transfer signal TGD. The SN node 22 temporarily accumulates these charges.

The intensity reading circuit 23 is configured by combining an amplification transistor 31, a selection transistor 32, and a reset transistor 33, and outputs an intensity signal corresponding to the amounts of light received by the PDs 13-1 to 13-4. The amplification transistor 31 generates an intensity signal according to the charge accumulated in the FD node 21, and when the intensity reading circuit 23 is selected by a selection signal SEL supplied to the selection transistor 32, the intensity signal is read via a vertical signal line VSL. Furthermore, the charge accumulated in the FD node 21 is discharged according to a reset signal RST supplied to the reset transistor 33, and the FD node 21 is reset.

The logarithmic conversion circuit 24 is configured by combining amplification transistors 41 and 42 and Log transistors 43 and 44, and connecting a constant current source 46 to the combination via a Cu—Cu contact section 45, and outputs a voltage signal of a voltage value obtained by logarithmically converting the amount of light received by the PDs 13-3 to 13-6 to a row selection circuit 51. Here, the voltage signal output from the logarithmic conversion circuit 24 is used in a logic circuit at a subsequent stage to detect that an event has occurred in a case where the voltage signal is equal to or more than a predetermined voltage value, and hereinafter, this voltage signal is also referred to as an event detection signal.

The row selection circuit 51 is configured by connecting a capacitor 52, an amplifier 53, a capacitor 54, and a switch 55, and outputs an event detection signal output from the logarithmic conversion circuit 24 to a logic circuit (not illustrated) according to a row selection signal for selecting pixels 12 in each row.

The image sensor 11 is thus configured, and the pixels 12-1 to 12-4 surrounded by a one-dot chain line form an intensity sharing unit that shares the FD node 21 and the intensity reading circuit 23, and the pixels 12-3 to 12-6 surrounded by a two-dot chain line form an event sharing unit that shares the SN node 22 and the logarithmic conversion circuit 24.

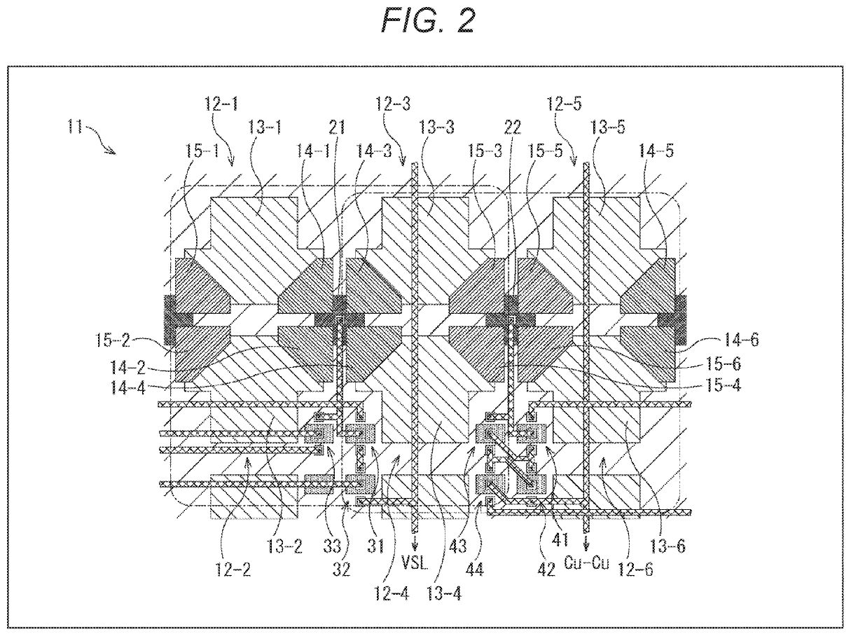

FIG. 2 is a wiring diagram illustrating an example of a wiring configuration in plan view of a sensor surface of the image sensor 11.

As illustrated in FIG. 2, among the six pixels 12-1 to 12-6 arranged in 3×2, the pixels 12-1 to 12-4 arranged in 4×4 surrounded by a one-dot chain line are the intensity sharing unit, and the pixels 12-3 to 12-6 arranged in 4×4 surrounded by a two-dot chain line are the event sharing unit.

The intensity sharing unit has a wiring configuration in which the amplification transistor 31, the selection transistor 32, and the reset transistor 33 included in the intensity reading circuit 23 are connected to the FD node 21 provided at the center of the pixels 12-1 to 12-4. The event sharing unit has a wiring configuration in which the amplification transistors 41 and 42 and the Log transistors 43 and 44 included in the logarithmic conversion circuit 24 are connected to the SN node 22 provided at the center of the pixels 12-3 to 12-6.

The image sensor 11 is thus configured, and the adopted pixel sharing structure in which the intensity reading circuit 23 and the logarithmic conversion circuit 24 are each shared by every four pixels 12 enables miniaturization of the pixels 12 or expansion of the area of the PDs 13. That is, since the image sensor 11 can reduce the number of necessary pixel transistors as compared with the conventional configuration in which it is necessary to provide the intensity reading circuit 23 and the logarithmic conversion circuit 24 for each pixel 12, it is possible to miniaturize the pixels 12 or expand the area of the PDs 13. As a result, the image sensor 11 can achieve miniaturization and high sensitivity as compared with the conventional configuration, and can improve performance.

Furthermore, the image sensor 11 is configured such that among the four pixels 12-1 to 12-4 serving as an intensity sharing unit and among the four pixels 12-3 to 12-6 serving as an event sharing unit, the pixels 12-3 and 12-4 share the same FD node 21 and SN node 22, that is, the sharing destinations thereof are the same. On the other hand, the image sensor 11 is configured such that the pixels 12-1 and 12-2 among the four pixels 12-1 to 12-4 serving as an intensity sharing unit and the pixels 12-5 and 12-6 among the four pixels 12-3 to 12-6 serving as an event sharing unit share different FD nodes 21 and SN nodes 22, that is, the sharing destinations thereof are different.

As described above, the image sensor 11 is configured such that sharing destinations of at least some of the pixels 12 are different between the intensity sharing unit and the event sharing unit, whereby the intervals between the TG transistors 14 and the TGD transistors 15 can be wide in plan view of the sensor surface. That is, the image sensor 11 is configured in a planar layout in which intervals between the TG transistors 14 and intervals between the TGD transistors 15 are narrow, and intervals between the TG transistors 14 and the TGD transistors 15 are wider than the intervals.

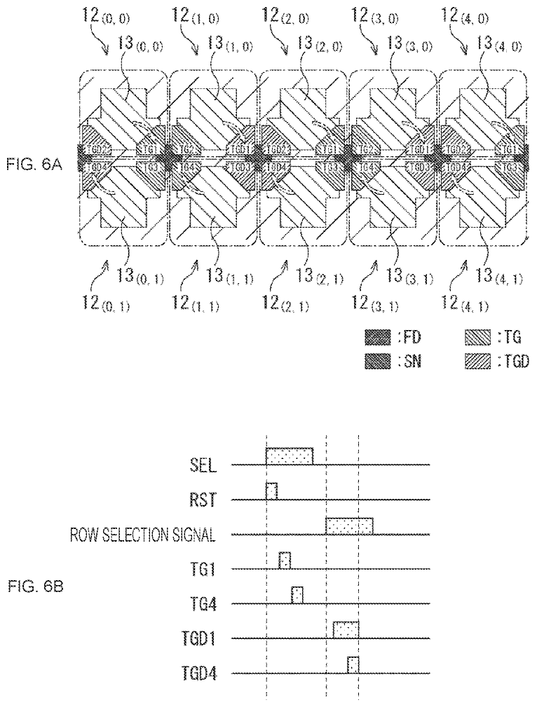

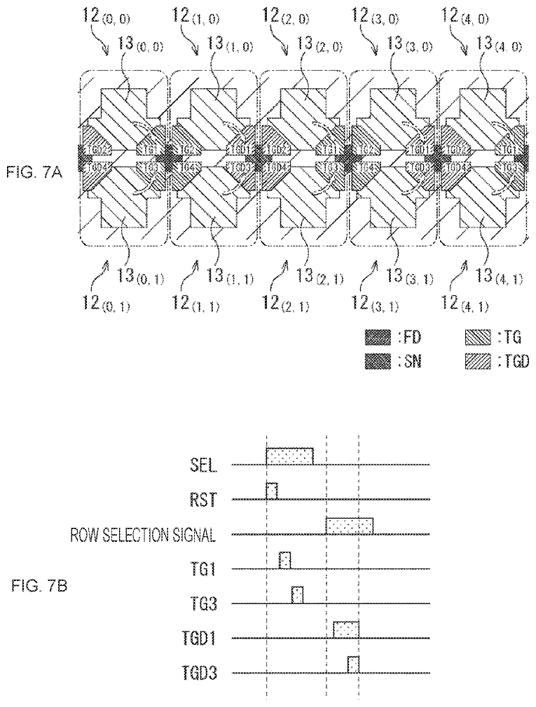

Therefore, the image sensor 11 can reduce interference between the TG transistors 14 and the TGD transistors 15 when they are simultaneously driven (for example, they are driven by a driving method of FIGS. 6 and 7 described later). Therefore, the image sensor 11 can suppress the occurrence of a detection error due to coupling of the control lines of the TG transistors 14 and the TGD transistors 15 as described above, and can further improve performance.

<Method of Driving Image Sensor>

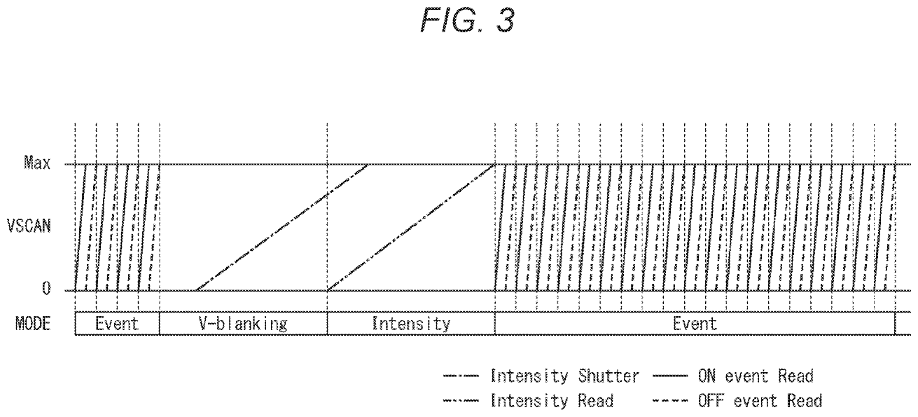

A method of driving the pixels 12 in the image sensor 11 will be described with reference to FIGS. 3 to 7.

FIG. 3 illustrates an example of a waveform of a vertical scanning signal VSCAN for driving the image sensor 11.

As illustrated in FIG. 3, the image sensor 11 can drive the pixels 12 by switching between an intensity detection period (V-blanking and Intensity) for detecting an intensity and an event detection period (Event) for detecting an event.

In the intensity detection period, the pixels 12 are driven so as to discharge the charge accumulated in the FD node 21 via the reset transistor 33 sequentially in the vertical direction according to the intensity shutter signal (Intensity Shutter) in the vertical blanking period. Subsequently, in the intensity reading period, the pixels 12 are driven so as to read the charges generated in the PDs 13 to the FD node 21 via the TG transistor 14 sequentially in the vertical direction according to the intensity reading signal (Intensity Read).

In the event detection period, driving of the pixels 12 for starting reading of the charges generated in the PDs 13 via the TGD transistors 15 and driving of the pixels 12 for ending the reading are alternately and repeatedly performed, sequentially in the vertical direction in accordance with event read on signals (ON event Read) and event read off signals (OFF event Read).

As described above, in a case where the pixels 12 are driven by switching between the intensity detection period and the event detection period, a basic driving method of the image sensor 11 is similar to that of a general complementary metal oxide semiconductor (CMOS) image sensor.

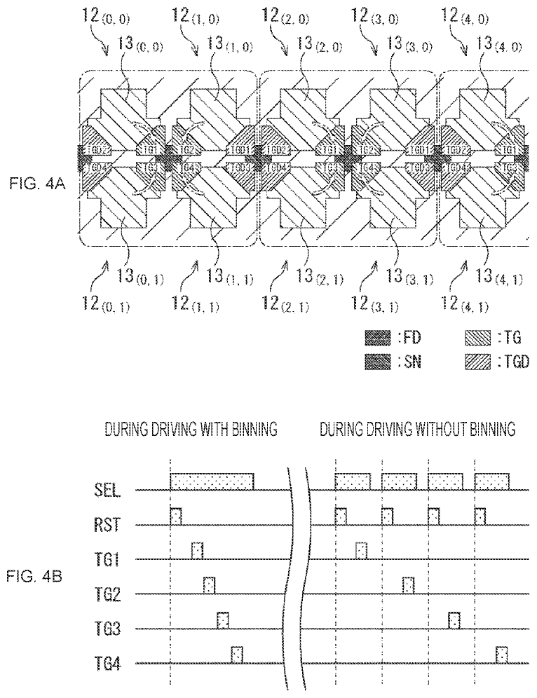

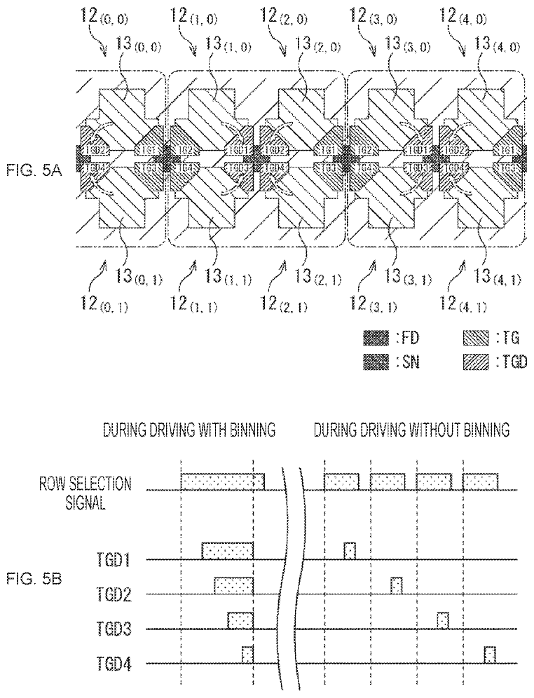

FIG. 4 is a diagram for describing driving in the intensity detection period of FIG. 3, and FIG. 5 is a diagram for describing driving in the event detection period of FIG. 3.

As illustrated in A of FIG. 4, in the intensity detection period, the pixel 12_{(2n, 2m)}, the pixel 12_{(2n, 2m+1)}, the pixel 12_{(2n+1, 2m)}, and the pixel 12_{(2n+1, 2m+1)} surrounded by a one-dot chain line are driven as an intensity sharing unit, and the charges are transferred to the FD node 21 as indicated by arrows outlined by one-dot chain lines. As illustrated in A of FIG. 5, in the event detection period, the pixel 12_{(2n+1, 2m)}, the pixel 12_{(2n+1, 2m+1)}, the pixel 12_{(2n+2, 2m)}, and the pixel 12_{(2n+2, 2m+1)} surrounded by a two-dot chain line are driven as an event sharing unit, and the charges are transferred to the SN node 22 as indicated by arrows outlined by two-dot chain lines. n and m are integers of 0 or more.

In the intensity detection period, the pixels 12 are driven in accordance with the selection signal SEL, the reset signal RST, and the transfer signals TG1 to TG4 as illustrated in B of FIG. 4. The transfer signal TG1 is supplied to the TG transistor 14 of the pixel 12_{(2n, 2m)}, the transfer signal TG2 is supplied to the TG transistor 14 of the pixel 12_{(2n+1, 2m)}, the transfer signal TG3 is supplied to the TG transistor 14 of the pixel 12_{(2n, 2m+1)}, and the transfer signal TG4 is supplied to the TG transistor 14 of the pixel 12_{(2n+1, 2m+1)}.

For example, during driving in which binning is performed, the pixels 12 are driven such that the selection signal SEL becomes the H level, the reset signal RST, the transfer signal TG1, the transfer signal TG2, the transfer signal TG3, and the transfer signal TG4 sequentially become the H level in pulse, and thereafter, the selection signal SEL becomes the L level. At the time of driving in which binning is not performed, the pixels 12 are driven such that the selection signal SEL becomes the H level, then the reset signal RST and the transfer signal TG1 sequentially become the H level in pulse, and thereafter, the selection signal SEL becomes the L level. Thereafter, similar driving is repeated for the transfer signals TG2 to TG4.

In the event detection period, the pixels 12 are driven in accordance with the row selection signal and the transfer signals TGD1 to TGD4 as illustrated in B of FIG. 5. The transfer signal TGD1 is supplied to the TGD transistor 15 of the pixel 12_{(2n+1, 2m)}, the transfer signal TGD2 is supplied to the TGD transistor 15 of the pixel 12_{(2n+2, 2m)}, the transfer signal TGD3 is supplied to the TGD transistor 15 of the pixel 12_{(2n+1, 2m+1)}, and the transfer signal TGD4 is supplied to the TGD transistor 15 of the pixel 12_{(2n+2, 2m+1)}.

For example, at the time of driving in which binning is performed, the pixels 12 are driven such that the row selection signal becomes the H level, the transfer signal TGD1, the transfer signal TGD2, the transfer signal TGD3, and the transfer signal TGD4 sequentially become the H level, the transfer signals TGD1 to TGD4 simultaneously become the L level, and thereafter, the row selection signal becomes the L level. At the time of driving in which binning is not performed, the row selection signal becomes the H level, the transfer signal TGD1 becomes the H level in pulse, and then the row selection signal becomes the L level, and thereafter, similar driving is repeated for the transfer signals TGD2 to TGD4.

In this manner, the image sensor 11 can drive the pixels 12 by switching between the intensity detection period and the event detection period.

Furthermore, the image sensor 11 can drive the pixels 12 with the intensity detection period and the event detection period in parallel by setting two pixels 12 out of the four pixels 12 as an intensity sharing unit and setting the other two pixels 12 as an event sharing unit, for example.

With reference to FIG. 6, a driving method will be described in which the pixels 12 are driven in parallel by setting the pixel 12_{(2n, 2m)} and the pixel 12_{(2n+1, 2m+1)} arranged in an oblique direction as an intensity sharing unit, and setting the pixels 12_{(2n+1, 2m)} and 12_{(2n+2, 2m+1)} arranged in an oblique direction as an event sharing unit.

That is, as illustrated in A of FIG. 6, the pixel 12_{(2n, 2m)} and the pixel 12_{(2n+1, 2m+1)} surrounded by a one-dot chain line are driven as an intensity sharing unit, and charges are transferred to the FD node 21 as indicated by arrows outlined by one-dot chain lines. Furthermore, the pixel 12_{(2n+1, 2m)} and the pixel 12_{(2n+2, 2m+1)} surrounded by a two-dot chain line are driven as an event sharing unit, and charges are transferred to the SN node 22 as indicated by arrows outlined by two-dot chain lines.

When the intensity sharing unit and the event sharing unit are set as described above, the pixels 12 are driven according to the selection signal SEL, the reset signal RST, the row selection signal, the transfer signals TG1 and TG4, and the transfer signals TGD1 and TGD4 as illustrated in B of FIG. 6. That is, the selection signal SEL becomes the H level, then the reset signal RST, the transfer signal TG1 and the transfer signal TG4 sequentially become the H level in pulse, and thereafter, the selection signal SEL becomes the L level. Subsequently, the pixels 12 are driven such that the row selection signal becomes the H level, the transfer signal TGD1 and the transfer signal TGD4 sequentially become the H level, the transfer signal TGD1 and the transfer signal TGD4 simultaneously become the L level, and thereafter, the row selection signal becomes the L level.

As described above, the image sensor 11 can drive the pixels 12 with the intensity detection period and the event detection period in parallel by setting, as an intensity sharing unit, two pixels arranged side by side in an oblique direction among the four pixels 12, and setting, as an event sharing unit, two pixels arranged side by side in an oblique direction adjacent to the intensity sharing unit.

With reference to FIG. 7, a driving method will be described in which the pixel 12_{(2k, 2m)} and the pixel 12_{(2k, 2m+1)} arranged in the vertical direction are set as an intensity sharing unit, and the pixel 12_{(2n+1, 2m)} and the pixel 12_{(2n+1, 2m+1)} arranged in the vertical direction are set as an event sharing unit.

That is, as illustrated in A of FIG. 7, the pixel 12_{(2n, 2m)} and the pixel 12_{(2n, 2m+1)} surrounded by a one-dot chain line are driven as an intensity sharing unit, and charges are transferred to the FD node 21 as indicated by arrows outlined by one-dot chain lines. Furthermore, the pixel 12_{(2n+1, 2m)} and the pixel 12_{(2n+1, 2m+1)} surrounded by a two-dot chain line are driven as an intensity sharing unit, and charges are transferred to the SN node 22 as indicated by arrows outlined by two-dot chain lines.

When the intensity sharing unit and the intensity sharing unit are set as described above, the pixels 12 are driven according to the selection signal SEL, the reset signal RST, the row selection signal, the transfer signals TG1 and TG3, and the transfer signals TGD1 and TGD3 as illustrated in B of FIG. 7. That is, the selection signal SEL becomes the H level, then the reset signal RST, the transfer signal TG1 and the transfer signal TG3 sequentially become the H level in pulse, and thereafter, the selection signal SEL becomes the L level. Subsequently, the pixels 12 are driven such that the row selection signal becomes the H level, the transfer signal TGD1 and the transfer signal TGD3 sequentially become the H level, the transfer signal TGD1 and the transfer signal TGD3 simultaneously become the L level, and thereafter, the row selection signal becomes the L level.

As described above, the image sensor 11 can drive the pixels 12 with the intensity detection period and the event detection period in parallel by setting, as an intensity sharing unit, two pixels arranged side by side in the vertical direction among the four pixels 12, and setting, as an event sharing unit, two pixels arranged side by side in the vertical direction adjacent to the intensity sharing unit.

<Arrangement Example of Transistors>

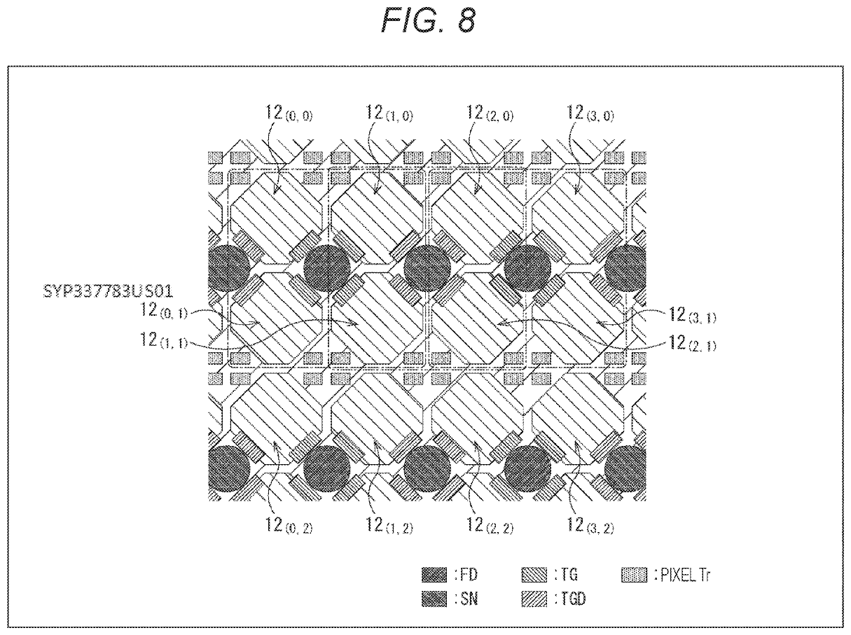

An arrangement example of the transistors included in the image sensor 11 will be described with reference to FIGS. 8 to 12.

Note that, in the following description, among various transistors used to drive the pixels 12, transistors other than the TG transistors 14 and the TGD transistors 15 are referred to as pixel Trs. For example, the pixel Trs include the amplification transistor 31, the selection transistor 32, the reset transistor 33, the amplification transistors 41 and 42, and the Log transistors 43 and 44.

FIG. 8 is a diagram illustrating a first arrangement example of the transistors.

As illustrated in FIG. 8, in the pixels 12_{(x, y)} arranged in a matrix, in the pixels 12_{(2n, 2m)}, the TGD transistors 15 are arranged at the lower left of the PDs 13, and the TG transistors 14 are arranged at the lower right of the PDs 13. In the pixels 12_{(2n, 2m+1)}, the TGD transistors 15 are arranged at the upper left of the PDs 13, and the TG transistors 14 are arranged at the upper right of the PDs 13. In the pixels 12_{(2n+1, 2m)}, the TGD transistors 15 are arranged at the lower right of the PDs 13, and the TG transistors 14 are arranged at the lower left of the PDs 13. In the pixels 12_{(2n+1, 2m+1)}, the TGD transistors 15 are arranged at the upper right of the PDs 13, and the TG transistors 14 are arranged at the upper left of the PDs 13.

That is, the TG transistors 14 and the TGD transistors 15 are alternately arranged in the row direction at positions below the PDs 13 of the pixels 12_{(2n, y)} in the even-numbered rows and above the PDs 13 of the pixels 12_{(2n+1, y)} in the odd-numbered rows.

Furthermore, the pixel Trs are arranged at the center of the four PDs 13 arranged in 2×2 at positions above the PDs 13 of the pixels 12_{(2n, y)} in the even-numbered rows and below the PDs 13 of the pixels 12_{(2n+1, y)} in the odd-numbered rows.

In the first arrangement example of the transistors as described above, the intensity sharing units and the event sharing units are arranged so as to be shifted from each other by one pixel in the row direction. That is, the intensity sharing units including the pixels 12_{(2n, 2m)}, the pixels 12_{(2n, 2m+1)}, the pixels 12_{(2n+1, 2m)}, and the pixels 12_{(2n+1, 2m+1)} and the event sharing units including the pixels 12_{(2n+1, 2m)}, the pixel 12_{(2n+1, 2m+1)}, the pixel 12_{(2n+2, 2m)}, and the pixel 12_{(2n+2, 2m+1)} are arranged to be shifted by one pixel in the row direction.

Specifically, the pixel 12_{(0, 0)}, the pixel 12_{(0, 1)}, the pixel 12_{(1, 0)}, and the pixel 12_{(1, 1)} surrounded by a one-dot chain line illustrated in FIG. 8 form an intensity sharing unit. Then, the pixel 12_{(1, 0)}, the pixel 12_{(1, 1)}, the pixel 12_{(2, 0)}, and the pixel 12_{(2, 1)} surrounded by a two-dot chain line at positions shifted by one pixel to the right in the row direction from the intensity sharing unit form an event sharing unit. Moreover, the pixel 12_{(2, 0)}, the pixel 12_{(2, 1)}, the pixel 12_{(3, 0)}, and the pixel 12_{(3, 1)} surrounded by a one-dot chain line at positions shifted by one pixel to the right in the row direction from the event sharing unit form an event sharing unit.

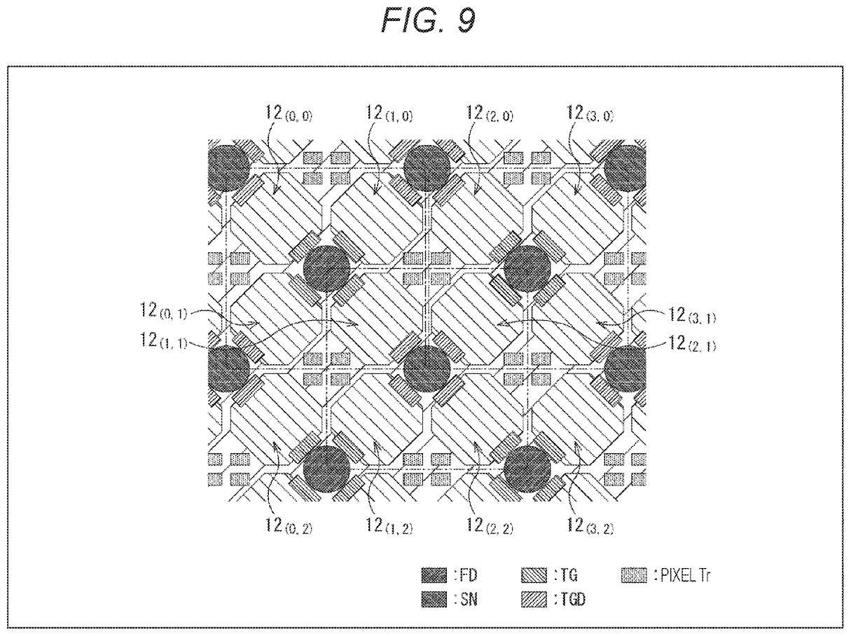

FIG. 9 is a diagram illustrating a second arrangement example of the transistors.

As illustrated in FIG. 9, in the pixels 12_{(x, y)} arranged in a matrix, in the pixels 12_{(2n, 2m)}, the TGD transistors 15 are arranged at the upper left of the PDs 13, and the TG transistors 14 are arranged at the lower right of the PDs 13. In the pixels 12_{(2n, 2m+1}), the TG transistors 14 are arranged at the upper right of the PDs 13, and the TGD transistors 15 are arranged at the lower left of the PDs 13. In the pixels 12_{(2n+1, 2m)}, the TGD transistors 15 are arranged at the upper right of the PDs 13, and the TG transistors 14 are arranged at the lower left of the PDs 13. In the pixels 12_{(2n+1, 2m+1)}, the TG transistors 14 are arranged at the upper left of the PDs 13, and the TGD transistors 15 are arranged at the lower right of the PDs 13.

That is, the TG transistors 14 are arranged at even-numbered positions in the row direction at positions below the PDs 13 of the pixels 12_{(2n, y)} in the even-numbered rows and above the PDs 13 of the pixels 12_{(2n+1, y)} in the odd-numbered rows. The TGD transistors 15 are arranged at odd-numbered positions in the row direction at positions above the PDs 13 of the pixels 12_{(2n, y)} in the even-numbered rows and below the PDs 13 of the pixels 12_{(2n+1, y)} in the odd-numbered rows. That is, the TG transistors 14 and the TGD transistors 15 are alternately arranged in the row direction and the column direction (that is, in the oblique direction).

Furthermore, the pixel Trs are arranged at the center of the four PDs 13 arranged in 2×2, at positions above the PDs 13 of the pixels 12_{(2n, y)} in the even-numbered rows and below the PDs 13 of the pixel 12_{(2n+1, y)} in the odd-numbered rows, and at positions below the PDs 13 of the pixels 12_{(2n, y)} in the even-numbered rows and above the PDs 13 of the pixels 12_{(2n+1, y)} in the odd-numbered rows.

In the second arrangement example of the transistors as described above, the intensity sharing units and the event sharing units are arranged so as to be shifted from each other by one pixel in the row direction and the column direction. That is, the intensity sharing units including the pixels 12_{(2n, 2m)}, the pixels 12_{(2n, 2m+1)}, the pixels 12_{(2n+1, 2m)}, and the pixels 12_{(2n+1, 2m+1)} and the event sharing units including the pixels 12_{(2n+1, 2m+1)}, the pixel 12_{(2n+1, 2m+2)}, the pixel 12_{(2n+2, 2m+1)}, and the pixel 12_{(2n+2, 2m+2)} are arranged to be shifted by one pixel in the row direction and the column direction.

Specifically, the pixel 12_{(0, 0)}, the pixel 12_{(0, 1)}, the pixel 12_{(1, 0)}, and the pixel 12_{(1, 1)} surrounded by a one-dot chain line illustrated in FIG. 9 form an intensity sharing unit. Then, the pixel 12_{(1, 1)}, the pixel 12_{(1, 2)}, the pixel 12_{(2, 1)}, and the pixel 12_{(2, 2)} surrounded by a two-dot chain line at positions shifted by one pixel to the right in the row direction and down in the column direction from the intensity sharing unit form an event sharing unit. Moreover, the pixel 12_{(2, 0)}, the pixel 12_{(2, 1)}, the pixel 12_{(3, 0)}, and the pixel 12_{(3, 1)} surrounded by a one-dot chain line at positions shifted by one pixel to the right in the row direction and up in the column direction from the event sharing unit form an event sharing unit.

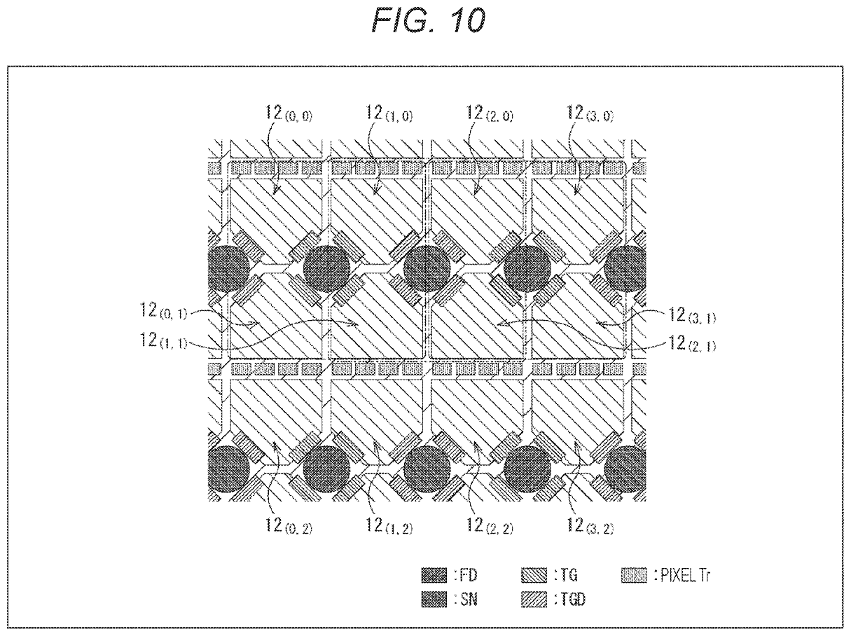

FIG. 10 is a diagram illustrating a third arrangement example of the transistors.

In the third arrangement example of the transistors illustrated in FIG. 10, the TG transistors 14 and the TGD transistors 15 are arranged similarly to the first arrangement example of the transistors described with reference to FIG. 8.

On the other hand, in the third arrangement example of the transistors, the arrangement of the pixel Trs is different from that of the first arrangement example of the transistors in FIG. 8. That is, the pixel Trs are arranged in a line along the row direction between adjacent PDs 13, at positions above the PDs 13 of the pixels 12_{(2n, y)} in the even-numbered rows and below the PDs 13 of the pixels 12_{(2n+1, y)} in the odd-numbered rows.

In the third arrangement example of the transistors as described above, the intensity sharing units and the event sharing units are arranged so as to be shifted from each other by one pixel in the row direction.

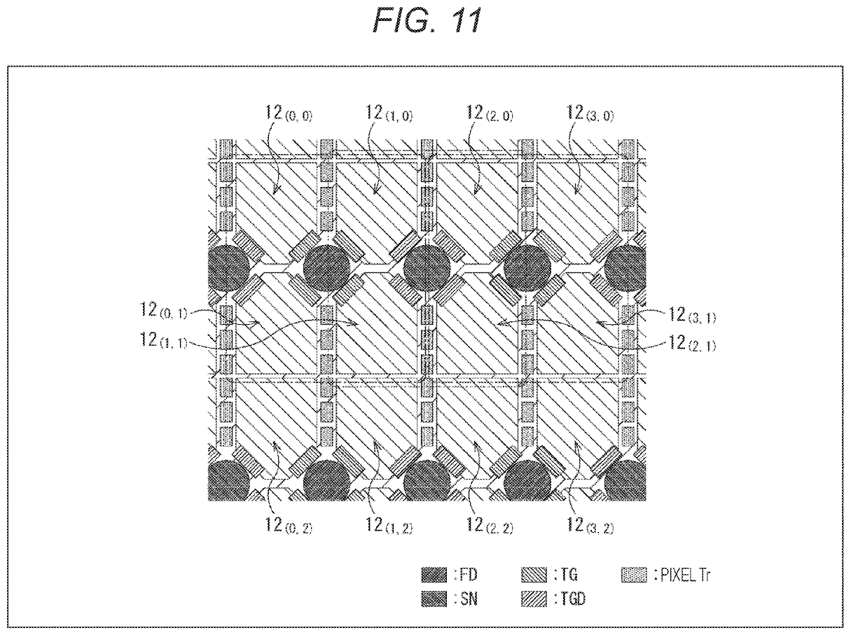

FIG. 11 is a diagram illustrating a fourth arrangement example of the transistors.

In the fourth arrangement example of the transistors illustrated in FIG. 11, the TG transistors 14 and the TGD transistors 15 are arranged similarly to the first arrangement example of the transistors described with reference to FIG. 8.

On the other hand, in the fourth arrangement example of the transistors, the arrangement of the pixel Trs is different from that of the first arrangement example of the transistors in FIG. 8. That is, the pixel Trs are arranged in a line along the column direction between adjacent PDs 13, at positions between the columns of the pixels 12.

In the fourth arrangement example of the transistors as described above, the intensity sharing units and the event sharing units are arranged so as to be shifted from each other by one pixel in the row direction.

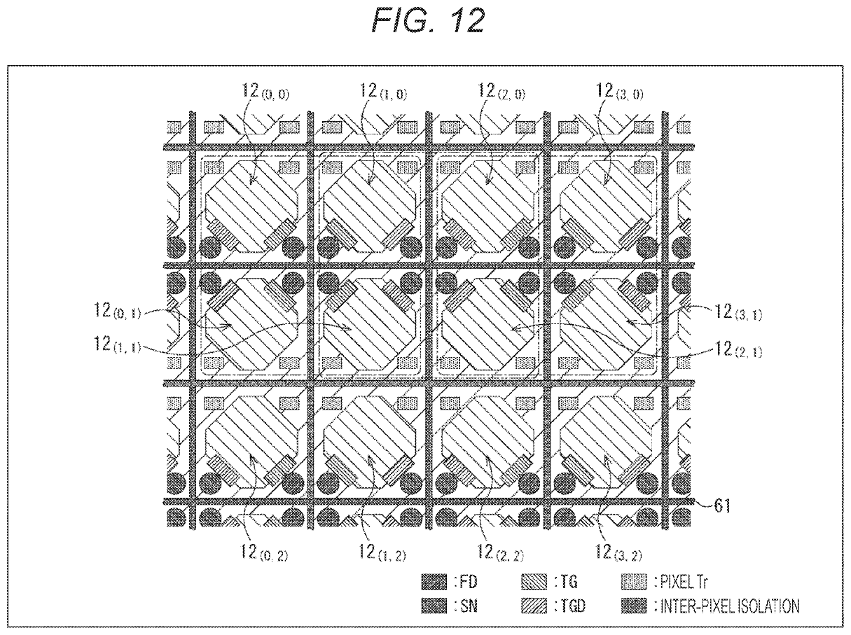

FIG. 12 is a diagram illustrating a fifth arrangement example of the transistors.

In the fifth arrangement example of the transistors illustrated in FIG. 12, inter-pixel isolation sections 61 that physically isolate the individual pixels 12 are provided. Since the pixels 12 are thus isolated by the inter-pixel isolation sections 61, the FD node 21 or the SN node 22 cannot be shared in the substrate, so that a configuration in which the FD nodes 21 and the SN nodes 22 included in the pixels 12 are connected by wiring to be shared is used.

Then, in the fifth arrangement example of the transistors, the TG transistors 14 and the TGD transistors 15 are arranged similarly to the first arrangement example of the transistors described with reference to FIG. 8. Furthermore, in the configuration, the pixel Trs are also arranged similarly to the first arrangement example of the transistors in FIG. 8, but the inter-pixel isolation sections 61 are provided between the pixel Trs of the pixels 12.

In the fifth arrangement example of the transistors as described above, the intensity sharing units and the event sharing units are arranged so as to be shifted from each other by one pixel in the row direction.

<Image Sensor of Multilayer Structure>

The image sensor 11 has a two-layer structure in which a sensor substrate on which the PDs 13 and the like are provided and a logic substrate on which logic substrates such as the row selection circuit 51 are provided are stacked via the Cu—Cu contact section 45 illustrated in FIG. 1. Moreover, the image sensor 11 can have a multilayer structure of two or more layers.

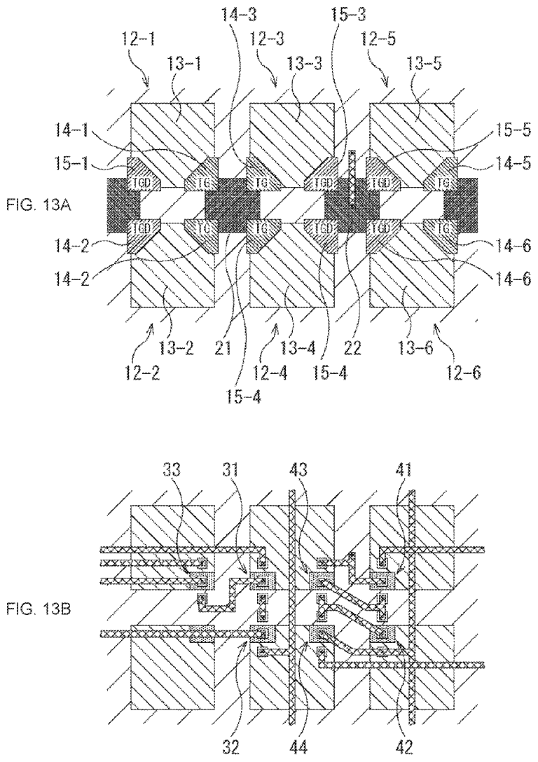

A configuration example of the image sensor 11 having a three-layer structure will be described with reference to FIG. 13.

For example, the image sensor 11 can have a three-layer structure in which a sensor substrate on which the PDs 13 and the like are provided, a transistor substrate on which the pixel transistors are provided, and a logic substrate on which logic substrates such as the row selection circuit 51 are provided are stacked. Note that the circuit configuration of the image sensor 11 having a three-layer structure is similar to the circuit diagram illustrated in FIG. 1.

A of FIG. 13 illustrates a planar layout of the sensor substrate, and the TG transistor 14 and the TGD transistor 15 are provided for each pixel 12.

B of FIG. 13 illustrates a planar layout of the transistor substrate, and the amplification transistor 31, the selection transistor 32, a reset transistor 33, the amplification transistors 41 and 42, and the Log transistors 43 and 44 are provided for the six pixels 12.

As described above, in the image sensor 11 having a three-layer structure, the area of the PDs 13 in the sensor substrate can be expanded by providing the pixel transistors on the transistor substrate. Therefore, the image sensor 11 can achieve higher sensitivity.

<Arrangement Example of Filters>

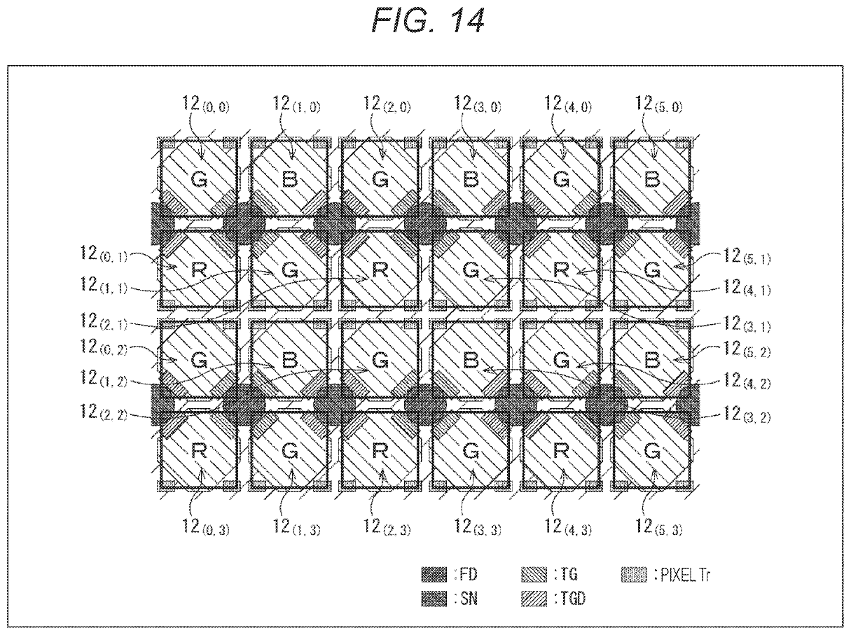

An arrangement example of filters stacked on the light receiving surface of the image sensor 11 will be described with reference to FIGS. 14 to 19.

FIG. 14 is a diagram illustrating a first arrangement example of the filters.

In the first arrangement example of the filters illustrated in FIG. 14, red filters R, green filters G, and blue filters B are arranged to form a Bayer array with respect to the first arrangement example of the transistors illustrated in FIG. 8. That is, in the Bayer array, the green filters G and the blue filters B are arranged alternately every pixel 12 in the row direction and the column direction, and the red filters R and the green filters G are arranged alternately every pixel 12 in the row direction and the column direction.

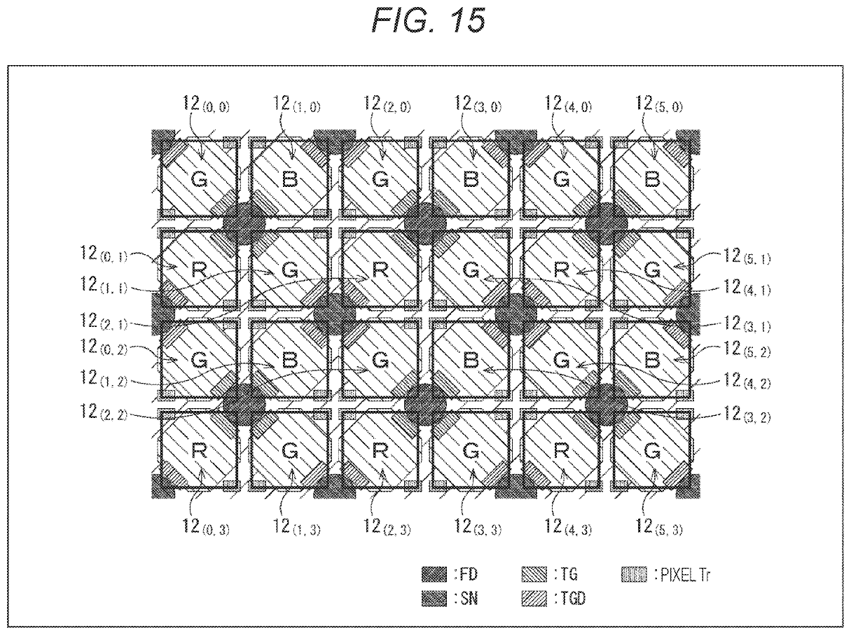

FIG. 15 is a diagram illustrating a second arrangement example of the filters.

In the second arrangement example of the filters illustrated in FIG. 15, red filters R, green filters G, and blue filters B are arranged to form a Bayer array with respect to the second arrangement example of the transistors illustrated in FIG. 9. That is, in the Bayer array, the green filters G and the blue filters B are arranged alternately every pixel 12 in the row direction and the column direction, and the red filters R and the green filters G are arranged alternately every pixel 12 in the row direction and the column direction.

In the image sensor 11 using the first and second arrangement examples of filters as described above, it is possible to acquire, at the FD node 21 and the SN node 22, all pieces of color information by reading charges via the TG transistor 14 and the TGD transistor 15 for each pixel.

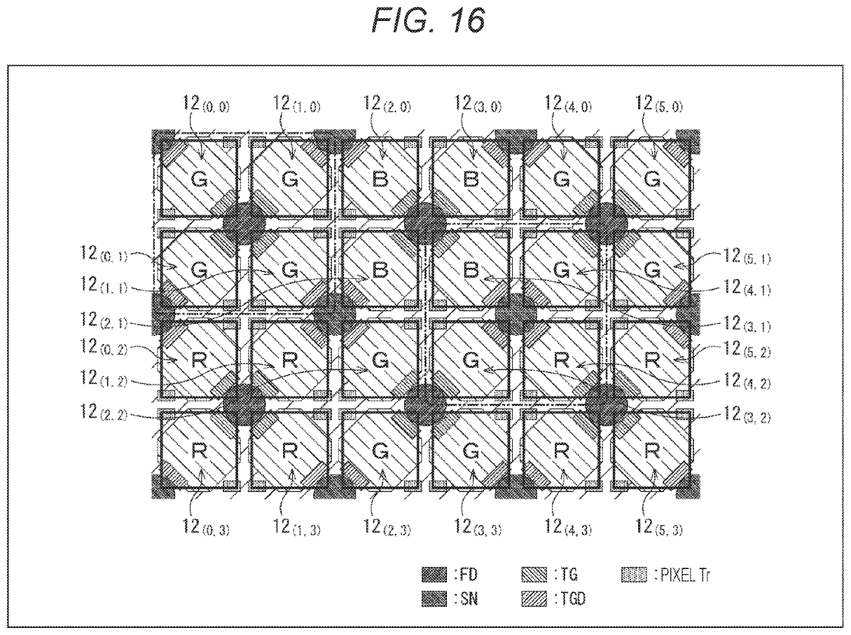

FIG. 16 is a diagram illustrating a third arrangement example of the filters.

In the third arrangement example of the filters illustrated in FIG. 16, red filters R, green filters G, and blue filters B are arranged in units of four pixels with respect to the second arrangement example of the transistors illustrated in FIG. 9 to form a Bayer array. That is, in the Bayer array of units of four pixels, the 4×4 green filters G and the 4×4 blue filters B are arranged alternately every four pixels 12 in the row direction and the column direction, and the 4×4 red filters R and the 4×4 green filters G are arranged alternately every four pixels 12 in the row direction and the column direction.

Moreover, in the third arrangement example of the filters, the red filters R, the green filters G, of the blue filters B are assigned to each unit of the four pixels 12 to be the intensity sharing unit so that the 4×4 filters of the same color coincide with the intensity sharing unit. Therefore, for the event sharing unit, the red filter R is assigned to one pixel 12, the green filters G are assigned to two pixels 12, and the blue filter B is assigned to one pixel 12.

In the image sensor 11 using the third arrangement example of the filters as described above, intensity signals can be synthesized for each intensity sharing unit in which filters of the same color are arranged, and sensitivity for each color can be improved.

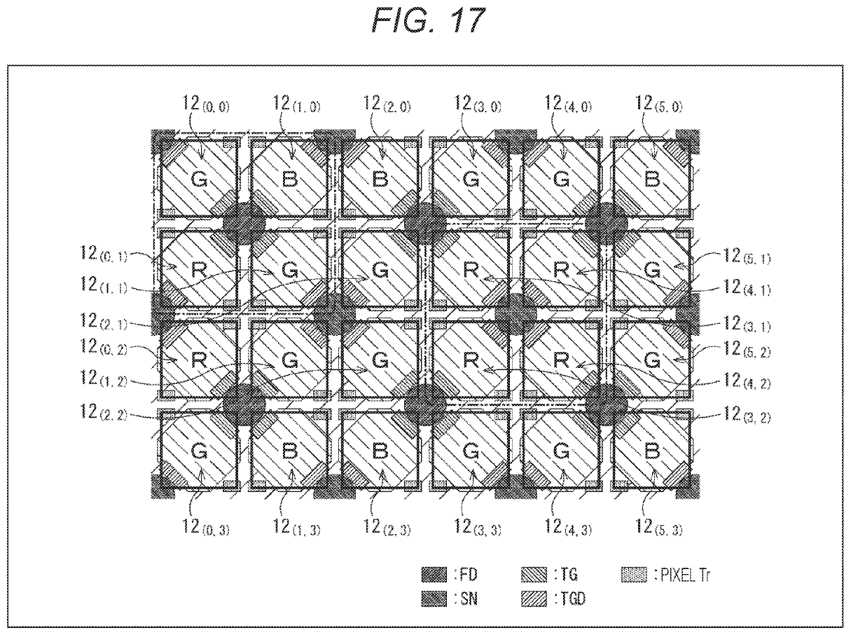

FIG. 17 is a diagram illustrating a fourth arrangement example of the filters.

In the fourth arrangement example of the filters illustrated in FIG. 17, red filters R, green filters G, and blue filters B are arranged in units of four pixels with respect to the second arrangement example of the transistors illustrated in FIG. 9 to form a Bayer array. That is, in the Bayer array of units of four pixels, the 4×4 green filters G and the 4×4 blue filters B are arranged alternately every four pixels 12 in the row direction and the column direction, and the 4×4 red filters R and the 4×4 green filters G are arranged alternately every four pixels 12 in the row direction and the column direction.

Moreover, in the fourth arrangement example of the filters, the red filters R, the green filters G, or the blue filters B are assigned to each unit of the four pixels 12 to be the event sharing unit so that the 4×4 filters of the same color coincide with the event sharing unit. Therefore, for the intensity sharing unit, the red filter R is assigned to one pixel 12, the green filters G are assigned to two pixels 12, and the blue filter B is assigned to one pixel 12.

In the image sensor 11 using the fourth arrangement example of filters as described above, event detection signals can be synthesized for each event sharing unit in which filters of the same color are arranged, and an event can be detected by capturing a finer change in light. Furthermore, the resolution of the intensity signal can be improved as compared with the third arrangement example of the filters of FIG. 16.

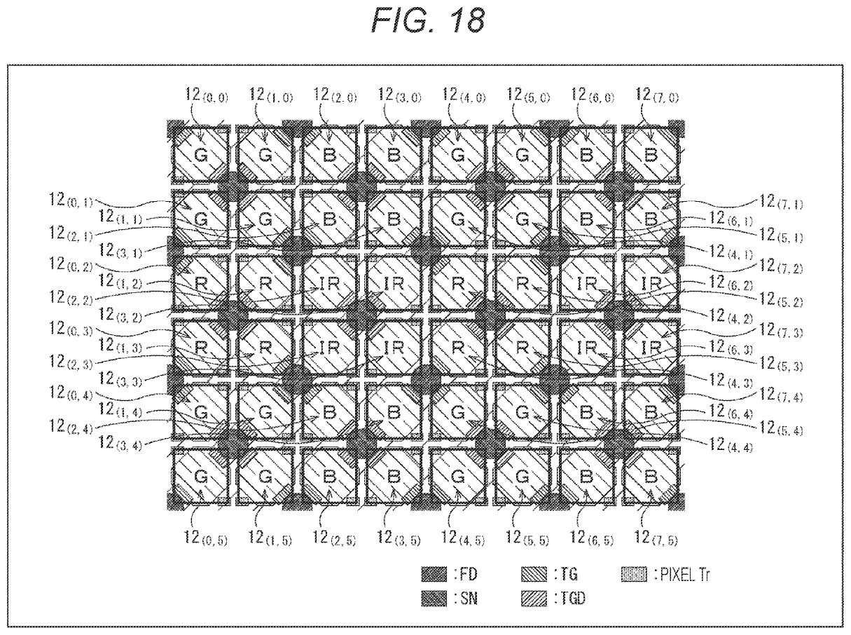

FIG. 18 is a diagram illustrating a fifth arrangement example of the filters.

In the fifth arrangement example of the filters illustrated in FIG. 18, in addition to red filters R, green filters G, and blue filters B, filters IR that transmit infrared light are arranged in pixels 12 included in an event sharing unit. That is, the red filters R, the green filters G, the blue filters B, or the filters IR are assigned to each unit of four pixels 12 to be an event sharing unit so that the 4×4 filters of the same color coincide with the event sharing unit, and three filters including a red filter R, a green filter G, and a blue filter B are assigned to an intensity sharing unit.

For example, the SN node 22 is shared and used by the 4×4 pixels 12 in which the filters IR are arranged. Furthermore, each of the FD nodes 21 arranged at the four corners of the 4×4 pixels 12 in which the filters IR are arranged is shared by a pixel 12 of a red filter R, a pixel 12 of a green filter G, and a pixel 12 of a blue filter B.

For example, in the example illustrated in FIG. 18, the SN node 22 arranged at the center of the pixel 12_{(2, 2)}, the pixel 12_{(2, 3)}, the pixel 12_{(3, 2)}, and the pixel 12_{(3, 3)} in which the filters IR are arranged is shared by these pixels 12. The FD node 21 arranged at the upper left of the pixel 12_{(2, 2)} is shared by the pixel 12_{(1, 2)} of a red filter R, the pixel 12_{(1, 1)} of a green filter G, and the pixel 12_{(2, 1)} of a blue filter B. The FD node 21 arranged at the lower left of the pixel 12_{(2, 3)} is shared by the pixel 12_{(1, 3)} of a red filter R, the pixel 12_{(1, 4)} of a green filter G, and the pixel 12_{(2, 4)} of a blue filter B. The FD node 21 arranged at the upper right of the pixel 12_{(3, 2)} is shared by the pixel 12_{(4, 2)} of a red filter R, the pixel 12_{(4, 1)} of a green filter G, and the pixel 12_{(3, 1)} of a blue filter B. The FD node 21 arranged at the lower right of the pixel 12_{(3, 3)} is shared by the pixel 12_{(4, 3)} of a red filter R, the pixel 12_{(4, 4)} of a green filter G, and the pixel 12_{(3, 4)} of a blue filter B.

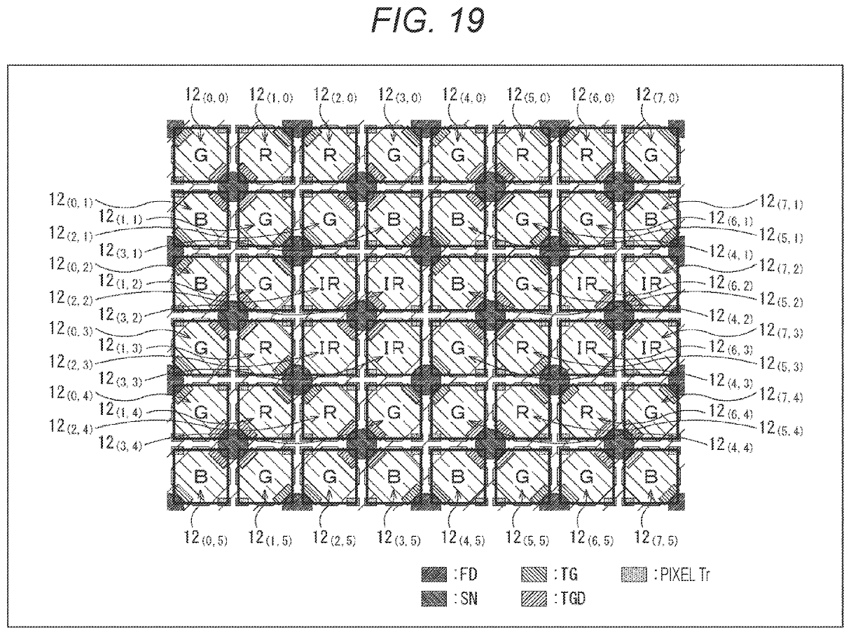

FIG. 19 is a diagram illustrating a sixth arrangement example of the filters.

In the ninth arrangement example of the filters illustrated in FIG. 19, in addition to red filters R, green filters G, and blue filters B, filters IR that transmit infrared light are arranged in pixels 12 included in an event sharing unit, and the filters IR are arranged such that 4×4 filters IR coincide with some of event sharing units.

For example, the SN node 22 is shared and used by the 4×4 pixels 12 in which the filters IR are arranged. Furthermore, among the FD nodes 21 arranged at the four corners of the 4×4 pixels 12 in which the filters IR are arranged, one FD node 21 is shared by pixels 12 of three red filters R, two FD nodes 21 each are shared by pixels 12 of three green filters G, and one FD node 21 is shared by pixels 12 of three blue filters B.

For example, in the example illustrated in FIG. 19, the SN node 22 arranged at the center of the pixel 12_{(2, 2)}, the pixel 12_{(2, 3)}, the pixel 12_{(3, 2)}, and the pixel 12_{(3, 3)} in which the filters IR are arranged is shared by these pixels 12. The FD node 21 arranged at the upper left of the pixel 12_{(2, 2)} is shared by the pixel 12_{(1, 2)} of a green filter G, the pixel 12_{(1, 1)} of the green filter G, and the pixel 12_{(2, 1)} of a green filter G. The FD node 21 arranged at the lower left of the pixel 12_{(2, 3)} is shared by the pixel 12_{(1, 3)} of a red filter R, the pixel 12_{(1, 4)} of a red filter R, and the pixel 12_{(2, 4)} of a red filter R. The FD node 21 arranged at the upper right of the pixel 12_{(3, 2)} is shared by the pixel 12_{(4, 2)} of a blue filter B, the pixel 12_{(4, 1)} of a blue filter of the green filter G, and the B, and the pixel 12_{(3, 1)} of a blue filter B. The FD node 21 arranged at the lower right of the pixel 12_{(3, 3)} is shared by the pixel 12_{(4, 3)} of a green filter G, the pixel 12_{(4, 4)} of the green filter G, and the pixel 12_{(3, 4)} of a green filter G.

In the image sensor 11 using the fifth and sixth arrangement examples of filters as described above, an event can be detected with higher sensitivity by 4×4 pixels 12 in which the filters IR are arranged.

<Configuration Example of Electronic Device>

The above-described image sensor 11 may be applied to various electronic devices such as an imaging system such as a digital still camera and a digital video camera, a mobile phone having an imaging function, or another device having an imaging function, for example.

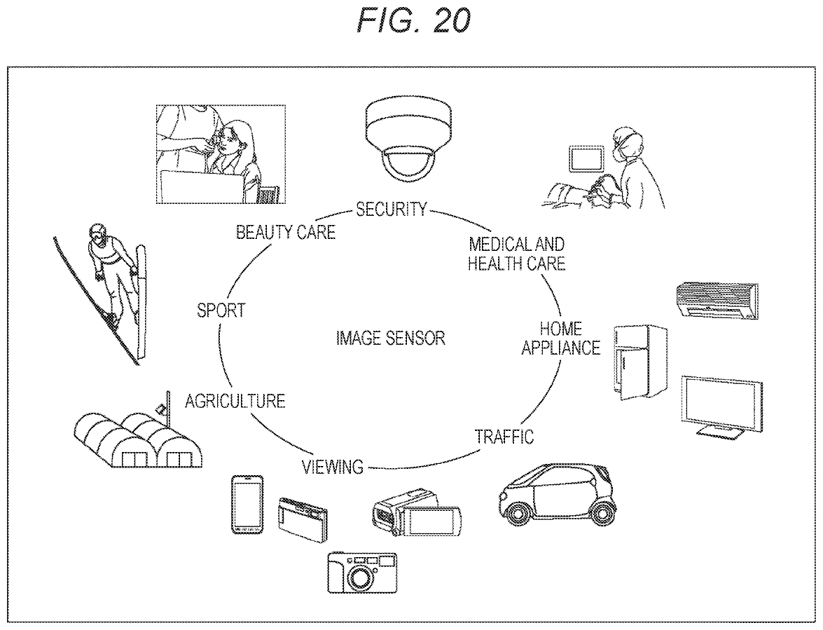

FIG. 20 is a block diagram illustrating a configuration example of an imaging device mounted on an electronic device.

As illustrated in FIG. 20, an imaging device 101 includes an optical system 102, an imaging element 103, a signal processing circuit 104, a monitor 105, and a memory 106, and may take a still image and a moving image.

The optical system 102 includes one or a plurality of lenses, and guides image light from an object (incident light) to the imaging element 103 to form an image on a light-receiving surface (sensor unit) of the imaging element 103.

As the imaging element 103, the image sensor 11 described above is used. Electrons are accumulated in the imaging element 103 for a certain period in accordance with the image formed on the light-receiving surface via the optical system 102. Then, a signal corresponding to the electrons accumulated in the imaging element 103 is supplied to the signal processing circuit 104.

The signal processing circuit 104 performs various types of signal processing on the pixel signal output from the imaging element 103. An image (image data) obtained by the signal processing applied by the signal processing circuit 104 is supplied to the monitor 105 to be displayed or supplied to the memory 106 to be stored (recorded).

The imaging device 101 configured as described above can capture, for example, a higher quality image when occurrence of an event is detected by using the above-described image sensor 11.

<Usage Example of Image Sensor>

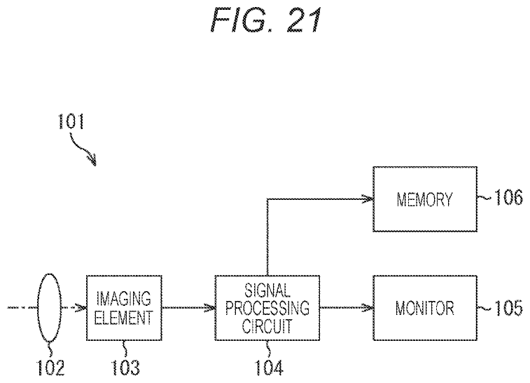

FIG. 21 is a diagram illustrating a use example of the above-mentioned image sensor (imaging element).

The above-described image sensor may be used in various cases in which light such as visible light, infrared light, ultraviolet light, and X-ray is sensed as hereinafter described, for example.

A device which takes an image to be used for viewing such as a digital camera and portable equipment with a camera function
A device for traffic purpose such as an in-vehicle sensor which takes images of the front, rear, surroundings, interior and the like of an automobile, a surveillance camera for monitoring traveling vehicles and roads, and a ranging sensor which measures a distance between vehicles and the like for safe driving such as automatic stop, recognition of a driver's condition and the like.
A device for home appliance such as a television, a refrigerator, and an air conditioner that takes an image of a user's gesture and performs a device operation according to the gesture
A device for medical and health care use such as an endoscope and a device that performs angiography by receiving infrared light
A device for security use such as a security monitoring camera and an individual authentication camera
A device for beauty care such as a skin measuring device that images skin and a microscope that images scalp
A device for sporting use such as an action camera and a wearable camera for sporting use and the like
A device for agricultural use such as a camera for monitoring land and crop states

<Combination Examples of Configurations>

Note that the present technology may have the following configurations.

(1)

An image sensor including:
a photoelectric conversion unit provided for each of a plurality of pixels arranged in a matrix on a sensor surface;
a first transfer transistor that transfers a charge generated by photoelectric conversion in the photoelectric conversion unit to a first node; and
a second transfer transistor that transfers a charge generated by photoelectric conversion in the photoelectric conversion unit to a second node different from the first node,
in which
at least a part of a predetermined number of the pixels included in a first sharing unit that shares and uses the first node and a predetermined number of the pixels included in a second sharing unit that shares and uses the second node have different sharing destinations.

(2)

The image sensor according to (1) described above, in which
the image sensor is configured to have a planar layout in which an interval between the first transfer transistor and the second transfer transistor is wider than an interval between a predetermined number of the first transfer transistors that transfer a charge to the first node and an interval between a predetermined number of the second transfer transistors that transfer a charge to the second node.

(3)

The image sensor according to (1) or (2) described above further including:
an intensity reading circuit that is supplied with a charge transferred to the first node and outputs an intensity signal according to the charge; and
a logarithmic conversion circuit that is supplied with a charge transferred to the second node and outputs an event detection signal obtained by logarithmically converting the charge.

(4)

The image sensor according to any one of (1) to (3) described above, in which the pixels are driven while a first detection period
in which detection is performed for the first sharing unit and a second detection period in which detection is performed for the second sharing unit are switched.

(5)

The image sensor according to any one of (1) to (3) described above, in which
the pixels are driven while a first detection period in which detection is performed for the first sharing unit and a second detection period in which detection is performed for the second sharing unit are in parallel.

(6)

The image sensor according to any one of (1) to (5) described above, in which
four of the pixels arranged in 4×4 are included in the first sharing unit, four of the pixels arranged in 4×4 are included in the second sharing unit, and the first sharing unit and the second sharing unit are arranged to be shifted from each other by one pixel in a row direction.

(7)

The image sensor according to any one of (1) to (5) described above, in which
four of the pixels arranged in 4×4 are included in the first sharing unit, four of the pixels arranged in 4×4 are included in the second sharing unit, and the first sharing unit and the second sharing unit are arranged to be shifted from each other by one pixel in a row direction and a column direction.

(8)

The image sensor according to (3) described above, in which
pixel transistors included in the intensity reading circuit and the logarithmic conversion circuit are arranged at a center of the photoelectric conversion unit arranged in 4×4.

(9)

The image sensor according to (3) described above, in which
pixel transistors included in the intensity reading circuit and the logarithmic conversion circuit are arranged in a line between adjacent ones of the photoelectric conversion units.

(10)

The image sensor according to any one of (1) to (9) described above further including
an inter-pixel isolation section that physically isolates adjacent ones of the pixels from each other.

(11)

The image sensor according to (3) described above, in which
the image sensor has a multilayer structure in which at least a first semiconductor substrate on which the photoelectric conversion unit is provided and a second semiconductor substrate on which pixel transistors included in the intensity reading circuit and the logarithmic conversion circuit are stacked.

(12)

The image sensor according to any one of (1) to (11) described above, in which
four of the pixels arranged in 4×4 are included in the first sharing unit, four of the pixels arranged in 4×4 are included in the second sharing unit, and the first sharing unit and the second sharing unit are arranged to be shifted from each other by one pixel in a row direction, and
a red filter, a green filter, or a blue filter is arranged in each of the pixels to form a Bayer array.

(13)

The image sensor according to any one of (1) to (11) described above, in which
four of the pixels arranged in 4×4 are included in the first sharing unit, four of the pixels arranged in 4×4 are included in the second sharing unit, and the first sharing unit and the second sharing unit are arranged to be shifted from each other by one pixel in a row direction and a column direction, and
a red filter, a green filter, or a blue filter is arranged in each of the pixels to form a Bayer array.

(14)

The image sensor according to any one of (1) to (11) described above, in which
four of the pixels arranged in 4×4 are included in the first sharing unit, four of the pixels arranged in 4×4 are included in the second sharing unit, and the first sharing unit and the second sharing unit are arranged to be shifted from each other by one pixel in a row direction and a column direction, and
red filters, green filters, or blue filters are arranged in the pixels in each unit of four pixels coinciding with four of the pixels as the first sharing unit, to form a Bayer array.

(15)

The image sensor according to any one of (1) to (11) described above, in which
four of the pixels arranged in 4×4 are included in the first sharing unit, four of the pixels arranged in 4×4 are included in the second sharing unit, and the first sharing unit and the second sharing unit are arranged to be shifted from each other by one pixel in a row direction and a column direction, and
red filters, green filters, or blue filters are arranged in the pixels in each unit of four pixels coinciding with four of the pixels as the second sharing unit, to form a Bayer array.

(16)

The image sensor according to any one of (1) to (12) described above, in which
infrared filters are arranged in the pixels included in the second sharing unit.

(17)

An electronic device including an image sensor, including:
a photoelectric conversion unit provided for each of a plurality of pixels arranged in a matrix on a sensor surface;
a first transfer transistor that transfers a charge generated by photoelectric conversion in the photoelectric conversion unit to a first node; and
a second transfer transistor that transfers a charge generated by photoelectric conversion in the photoelectric conversion unit to a second node different from the first node,
in which
at least a part of a predetermined number of the pixels included in a first sharing unit that shares and uses the first node and a predetermined number of the pixels included in a second sharing unit that shares and uses the second node have different sharing destinations.

Note that the present embodiment is not limited to the above-described embodiment, and various modifications can be made without departing from the gist of the present disclosure. Furthermore, the effects described in the present specification are merely examples and are not limited, and other effects may be provided.

### REFERENCE SIGNS LIST

11 Image sensor
12 Pixel
13 PD
14 TG transistor
15 TGD transistor 15
21 FD node
22 SN node
23 Intensity reading circuit
24 Logarithmic conversion circuit
31 Amplification transistor
32 Selection transistor
33 Reset transistor
41 and 42 Transfer transistor
43 and 44 Log transistor
45 Cu—Cu contact section
46 Constant current source
51 Row selection circuit
52 Capacitor
53 Amplifier
54 Capacitor
55 Switch
61 Inter-pixel isolation section

1. An image sensor comprising:
a photoelectric conversion unit provided for each of a plurality of pixels arranged in a matrix on a sensor surface;
a first transfer transistor that transfers a charge generated by photoelectric conversion in the photoelectric conversion unit to a first node; and
a second transfer transistor that transfers a charge generated by photoelectric conversion in the photoelectric conversion unit to a second node different from the first node,
wherein
at least a part of a predetermined number of the pixels included in a first sharing unit that shares and uses the first node and a predetermined number of the pixels included in a second sharing unit that shares and uses the second node have different sharing destinations.

2. The image sensor according to claim 1, wherein
the image sensor is configured to have a planar layout in which an interval between the first transfer transistor and the second transfer transistor is wider than an interval between a predetermined number of the first transfer transistors that transfer a charge to the first node and an interval between a predetermined number of the second transfer transistors that transfer a charge to the second node.

3. The image sensor according to claim 1 further comprising:
an intensity reading circuit that is supplied with a charge transferred to the first node and outputs an intensity signal according to the charge; and
a logarithmic conversion circuit that is supplied with a charge transferred to the second node and outputs an event detection signal obtained by logarithmically converting the charge.

4. The image sensor according to claim 1, wherein
the pixels are driven while a first detection period in which detection is performed for the first sharing unit and a second detection period in which detection is performed for the second sharing unit are switched.

5. The image sensor according to claim 1, wherein
the pixels are driven while a first detection period in which detection is performed for the first sharing unit and a second detection period in which detection is performed for the second sharing unit are in parallel.

6. The image sensor according to claim 1, wherein
four of the pixels arranged in 4×4 are included in the first sharing unit, four of the pixels arranged in 4×4 are included in the second sharing unit, and the first sharing unit and the second sharing unit are arranged to be shifted from each other by one pixel in a row direction.

7. The image sensor according to claim 1, wherein
four of the pixels arranged in 4×4 are included in the first sharing unit, four of the pixels arranged in 4×4 are included in the second sharing unit, and the first sharing unit and the second sharing unit are arranged to be shifted from each other by one pixel in a row direction and a column direction.

8. The image sensor according to claim 3, wherein
pixel transistors included in the intensity reading circuit and the logarithmic conversion circuit are arranged at a center of the photoelectric conversion unit arranged in 4×4.

9. The image sensor according to claim 3, wherein
pixel transistors included in the intensity reading circuit and the logarithmic conversion circuit are arranged in a line between adjacent ones of the photoelectric conversion units.

10. The image sensor according to claim 1 further comprising
an inter-pixel isolation section that physically isolates adjacent ones of the pixels from each other.

11. The image sensor according to claim 3, wherein
the image sensor has a multilayer structure in which at least a first semiconductor substrate on which the photoelectric conversion unit is provided and a second semiconductor substrate on which pixel transistors included in the intensity reading circuit and the logarithmic conversion circuit are stacked.

12. The image sensor according to claim 1, wherein
four of the pixels arranged in 4×4 are included in the first sharing unit, four of the pixels arranged in 4×4 are included in the second sharing unit, and the first sharing unit and the second sharing unit are arranged to be shifted from each other by one pixel in a row direction, and
a red filter, a green filter, or a blue filter is arranged in each of the pixels to form a Bayer array.

13. The image sensor according to claim 1, wherein
four of the pixels arranged in 4×4 are included in the first sharing unit, four of the pixels arranged in 4×4 are included in the second sharing unit, and the first sharing unit and the second sharing unit are arranged to be shifted from each other by one pixel in a row direction and a column direction, and
a red filter, a green filter, or a blue filter is arranged in each of the pixels to form a Bayer array.

14. The image sensor according to claim 1, wherein
four of the pixels arranged in 4×4 are included in the first sharing unit, four of the pixels arranged in 4×4 are included in the second sharing unit, and the first sharing unit and the second sharing unit are arranged to be shifted from each other by one pixel in a row direction and a column direction, and
red filters, green filters, or blue filters are arranged in the pixels in each unit of four pixels coinciding with four of the pixels as the first sharing unit, to form a Bayer array.

15. The image sensor according to claim 1, wherein
four of the pixels arranged in 4×4 are included in the first sharing unit, four of the pixels arranged in 4×4 are included in the second sharing unit, and the first sharing unit and the second sharing unit are arranged to be shifted from each other by one pixel in a row direction and a column direction, and
red filters, green filters, or blue filters are arranged in the pixels in each unit of four pixels coinciding with four of the pixels as the second sharing unit, to form a Bayer array.

16. The image sensor according to claim 1, wherein
infrared filters are arranged in the pixels included in the second sharing unit.

17. An electronic device including an image sensor, comprising:
a photoelectric conversion unit provided for each of a plurality of pixels arranged in a matrix on a sensor surface;
a first transfer transistor that transfers a charge generated by photoelectric conversion in the photoelectric conversion unit to a first node; and
a second transfer transistor that transfers a charge generated by photoelectric conversion in the photoelectric conversion unit to a second node different from the first node,
wherein
at least a part of a predetermined number of the pixels included in a first sharing unit that shares and uses the first node and a predetermined number of the pixels included in a second sharing unit that shares and uses the second node have different sharing destinations.
